(19) United States
(12) Patent Application Publication
(10) Pub. No.: US 2006/0219289 A1
(43) Pub. Date: Oct. 5, 2006

(54) Combined photoelectrochemical cell and capacitor

(76) Inventors: Igor Lvovich Skryabin, Yarralumla, ACT (AU); Sylvia Medlyn Tulloch, (US)

Correspondence Address: DAVIS & BUJOLD, P.L.L.C., 112 PLEASANT STREET, CONCORD, NH, 03301, US

(21) Appl. No.: 10/570,530

(22) PCT Filed: May 21, 2004
(86) PCT No.: PCT/AU04/00689

§ 371 Date: Mar. 3, 2006

(30) Foreign Application Priority Data
May 21, 2003 (AU) 2003902456

(51) Int. Cl. H02N 6/00; H01L 31/00

(52) U.S. Cl. 136/244; 136/263

(57) ABSTRACT

A nanophotocapacitive device wherein: a photovoltaic element (1) extends over substantially the whole area of the device, a charge storage element (3) also extends over substantially the whole area of the device, connection mechanism (14) are provided for interconnecting the photovoltaic and charge storage elements, the photovoltaic element comprises a nanoparticulate dye sensitized layer (11) of wide band gap semiconductor, a catalytic layer (13) and an electrolyte (12) placed between the semiconductor and the catalytic layers. The photovoltaic (photoelectrochemical) element and charge storage element (capacitor) are formed on opposite sides of a titanium foil substrate (8). Light (16) is incident on the transparent electrode (15). A diode (2) may be integral with the device to prevent the charge storage element discharging when there is no solar energy input to the photovoltaic element.

### TECHNICAL FIELD

This invention relates to combined electrical energy storage (ES) and photovoltaic (PV) devices and more particularly, but not exclusively, to such devices suitable for use as solar chargers/boosters for wireless electronic products (e.g. computer notebooks, sensors, mobile phones).

### BACKGROUND TO THE INVENTION

The photovoltaic devices to which this invention is applicable will generally be used for wireless electronic applications. That is, they typically are connected to a rechargeable battery of a wireless product to maintain high charge state of the product. Power demand of a wireless product is typically non-uniform. It is high for short periods of processing large amounts of data and low—for relatively long periods of standby state.

Prior art discloses examples of ES devices: batteries and capacitors.

A photovoltaic (PV) cell can be used to supply additional energy to ES device. An additional diode element would be required to prevent discharging of ES and of the through the PV. It is inconvenient, however, to have as many additional elements in power supply line of the wireless devices. Each element adds to weight, complexity and failure probability.

### OBJECTIVES OF THE INVENTION

It is therefore an object of the present invention to provide a photovoltaic device suitable for use in wireless electronic devices and which is capable to generate and store electrical energy. There is a need for these devices that would provide:
Emergency power for battery switching;
Storage life extension for batteries through PV charging;
Better utilization of batteries through capacitive support.

### OUTLINE OF INVENTION

This invention is based upon the realisation that certain types of PV and ES cells or charge storage cells (CS) are based on electrochemical principles, and, thus fabricated using similar manufacturing techniques. The PV cells, which are particularly suitable for purpose are the regenerative photoelectrochemical Graetzel cells disclosed in the international patents WO 91/16719 (PCT/EP/00734) and WO 96/08022 (PCT/EP95/03459). The CS cells, which are particularly suitable for this purpose, are also generally known (rechargeable batteries, electrolytic capacitors). Essential that both PV devices of the type disclosed are based on nano-particulate layers.

In broad terms, the present invention comprises a photovoltaic device including a photovoltaic element (PV) and a charge storage (CS) element each covering the area of said device. The PV and CS elements may be formed by layering them on one side of a common transparent substrate pane of glass or plastic material, by forming them on opposite sides of a single pane, by sandwiching them together between a pair of panes, by forming each element separately between a pair of panes (so that the complete device is made up of three or four substrate panes).

The invention also provides for incorporating a diode element that covers part or substantially whole area of the said device.

It is preferable to form a PV element Is a Dye Sensitised Solar Cell.

From another aspect, the present invention comprises a combined photovoltaic and storage device including:
An electrically conductive substrate,
A PV element
A CS element
Means of internal connection between the said PV and capacitive elements
   When the said PV element is a Dye Sensitised Solar Cell, the PV element comprises: a dye sensitised nanoparticulate semiconducting layer, an electrolyte and a counter electrode layer.

The said CS element is preferably a capacitive element, for example an electrolytic capacitor with high surface area carbon based electrode.

The invention provides for forming both PV and CS elements on one conductive substrate. The said substrate can be a metal substrate (e.g. Ti, W, Ni, Cr foil or Stainless Steel). In some cases a protective coating is benefitial. The protective coating can be made of diamond or semimetallic or metallic nitrides, carbides, oxides, borides, phosphides, sulphides, silicides, antimonides, arsenides, tellurides and combinations thereof. Still preferable materials for the protective coating are TiN and ZrN.

Alternatively the elements may be formed on conductive polymer substrate or on a glass substrate coated from both side by an electrically conductive material.

Typically the PV and CS elements are formed on the opposite sides of the substrate.

The invention also provides for incorporation of a diode element. The said diode element is electrically connected to both PV and CS elements and formed in such a way, that electrical energy generated by the PV element is transferred without losses to the CS element and further to the battery of a wireless electronic device, but the electrical energy stored in the CS element or in the battery of the wireless device could not be transferred back to the PV element, thus preventing the CS element and the battery of the wireless device from discharging, when solar energy input to the said PV element is not sufficient.

The said diode element comprises at least 2 layers electrical properties of which are adjusted in such a way, that rectifying p-n junction is formed on interface between these 2 layers.

In one embodiment the said 2 layers of the diode layers are based on the semiconducting oxide. One of these two layers is doped with donor-, and another—with acceptor dopant.

In another embodiment the said semiconducting oxide is the same material as used in the PV cell for the formation of dye sensitised nanoparticulate semiconducting layer.

In still another embodiment the PV element comprises plurality of the PV cells interconnected (in series and/or in parallel) to form a power output that is suitable for the selected CS element and for a battery of a wireless device.

In further embodiment, the CS element comprises plurality of the CS cells interconnected (in series and/or in parallel) to suit power output of the PV element and requirements of a battery of a wireless device.

In some cases a layer with charge storage properties (e.g.—porous carbon, BaTiO₂)) is used within the device.

### DESCRIPTION OF EXAMPLES

Having portrayed the nature of the present invention, a number of particular examples will now be described by way of illustration only. In the following description, reference will be made to the accompanying drawings in which:

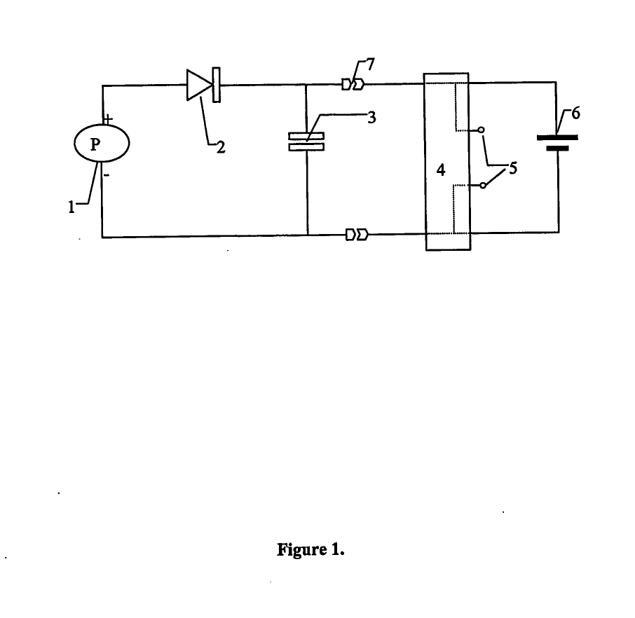

FIG. 1 presents equivalent electrical circuit elements of a combined PV and charge storage device connected to a battery, the device is to be illuminated from the working electrode side of the PV element. This device comprises the first example of the present invention.

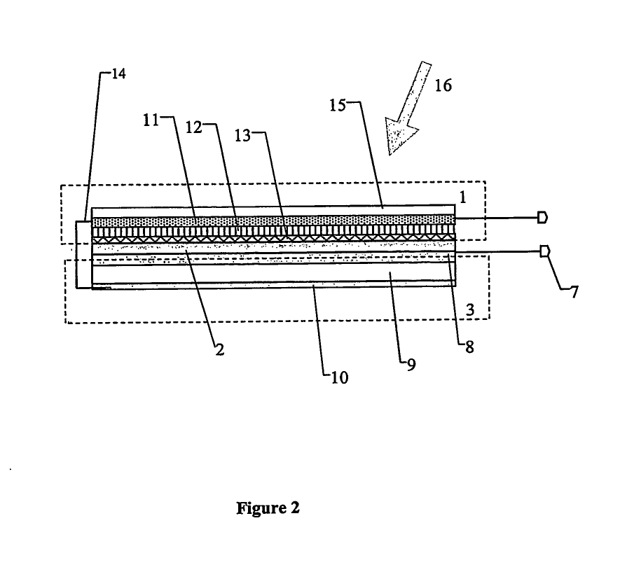

FIG. 2 is a diagrammatic cross-section illustrating the physical construction (not to scale) of a combined PV and charge storage device to be illuminated from the working electrode side of the PV element comprising the first example of the present invention.

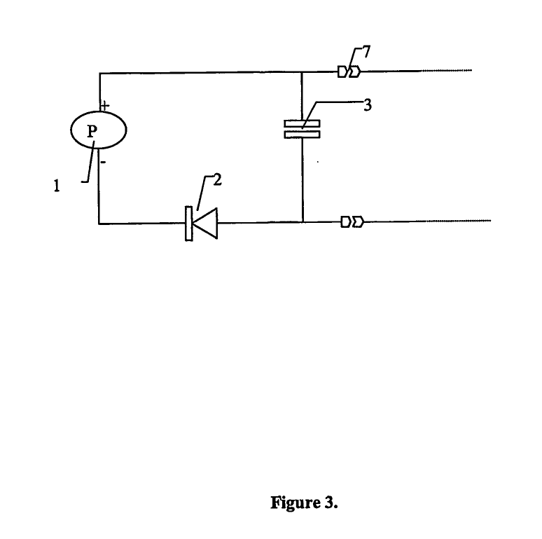

FIG. 3 is the equivalent electrical circuit of a combined PV and charge storage device to be illuminated from the counter electrode side of the PV element comprising the second example of the present invention.

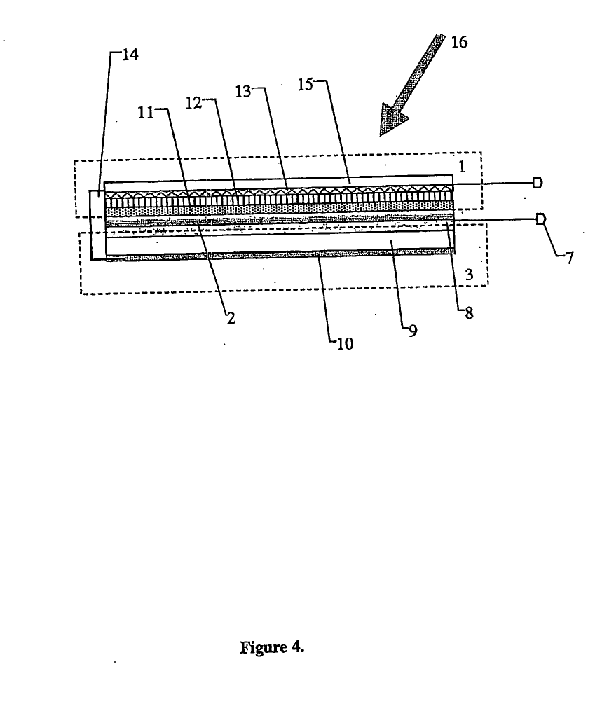

FIG. 4 is a diagrammatic cross-section illustrating the physical construction (not to scale) of a combined PV and charge storage device to be illuminated from the counter electrode side of the PV element comprising the second example of the present invention.

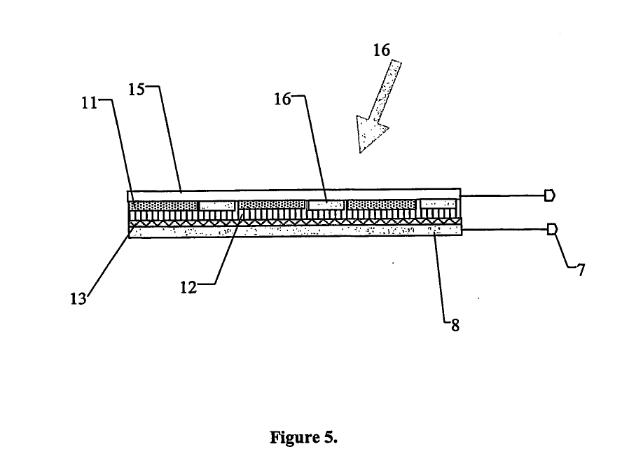

FIG. 5 is a diagrammatic cross-section illustrating the physical construction (not to scale) of a combined PV and charge storage device to be illuminated from the working electrode side of the PV element comprising the third example of the present invention

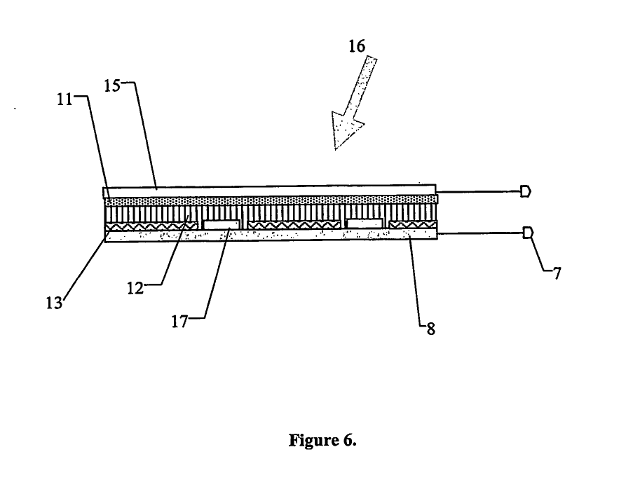

FIG. 6 is a diagrammatic cross-section illustrating the physical construction (not to scale) of a combined PV and charge storage device to be illuminated from the working electrode side of the PV element comprising the fourth example of the present invention

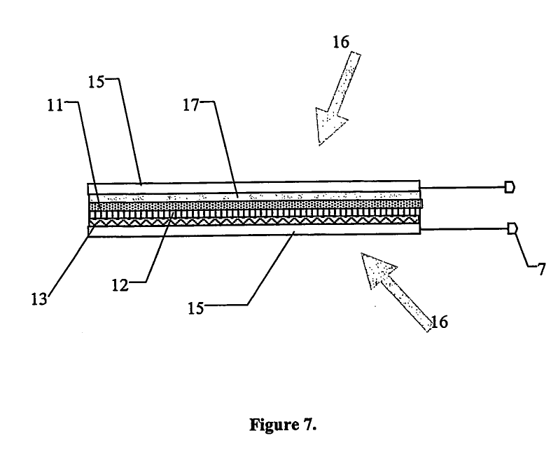

FIG. 7 is a diagrammatic cross-section illustrating the physical construction (not to scale) of a combined PV and charge storage device to be illuminated from either working or counter electrode side of the PV element comprising the fourth example of the present invention

Referring to FIG. 1, the combined PV and charge storage device of the first example comprises a PV element 1, a charge storage element 3 and a diode element 2, placed in the electrical circuit between counter electrode of the PV element and CS element. The device of this example is connected via connectors 7 to the interfacing electronics 4 to condition output of the device to the specific requirements of the battery 6 and of a wireless electronic device that is to be connected to the electrical terminals 5.

Referring to FIG. 2, the device of the first example is formed on titanium foil substrate 8. The layers of the diode element 2 are formed on the top side of the substrate. TiO₂ nanoparticulate layer is applied by screen-printing followed by firing to the transparent conductive electrode 15. Nanoparticulate titania is further sensitised with Ru based dye to form layer 11 of the device. The dye sensitised nanoparticulate layer 11 is separated from the counter electrode layer 13 deposited on the top layer of the diode element 2 by an electrolyte 12. All the component of the PV element of this example are typical for Dye Sensitised Solar Cell technology and broadly described in the prior art. A CS layers 9 are formed on the other side of the substrate 8 in such a way that electrically conductive substrate 8 serves as the first electrical terminal of the CS element 3. The CS element was manufactured using technology for high surface area carbon based electrolytic capacitors described in the prior art. The second electrical terminal 10 of the CS element 3 is electrically internally connected (14) to the transparent electrically conductive electrode 15 of the PV element 1. External electrical connections 7 are formed by extending wires from the transparent electrically conductive electrode 15 and electrically conductive substrate 8. The device is to be illuminated by light rays 16 incident to the transparent electrode 15.

Referring to FIG. 3, the device of the second example comprises the same elements as the device of the first example rearranged in such a way, that the diode element is now placed between the working electrode of the PV element 2 and SC element 3.

Referring to FIG. 4, the device of the second example comprises the same layers as the device of the first example, but those layers are rearranged to allow the light rays 16 to strike the PV element from the counter electrode side. In this case the working electrode of the PV element is formed on the substrate 8.

Referring to FIG. 5 a conductive transparent substrate 15 supports both a dye sensitsed titania layer 11 and a charge storage layer 17 (e.g. high surface area carbon or carbon nano-tubes). A counter electrode 13 of the device is formed in the same way as the counter electrode of the device of the first example. The counter electrode is supported by electrically conductive substrate 8. External electrical connections 7 are to be utilised for outputting electrical energy generated and stored within the device.

Referring to FIG. 6 a conductive substrate 8 supports both a catalytic layer 13 and a charge storage layer 17 External electrical connections 7 are to be utilised for outputting electrical energy generated and stored within the device.

Referring to FIG. 7 a device of the fifth example is formed between two conductive transparent substrates 15. A charge storage layer 17 of this example (e.g. doped TiO₂, BaTiO₂) is placed between a dye-sensitised layer 11 and the first transparent conductive substrate 15. A catalytic layer 13 is formed on the second transparent conductive substrate 15.

Though the examples described above fulfil the objectives of the invention and exhibit the desired advantages, it will be appreciated by those skilled in the art that many modifications and alterations can be made without departing from the scope of the invention as outlined above.

1-14. (canceled)

15. A nanophotocapacitive device comprising:
a photovoltaic element extends over substantially a whole area of the nanophotocapacitive device;
a charge storage element extends over substantially the whole area of the nanophotocapacitive device; and
connection means are provided for interconnecting the photovoltaic and the charge storage elements,
the photovoltaic element comprises a nanoparticulate dye sensitized layer of wide band gap semiconductor, a catalytic layer and an electrolyte placed between the semiconductor and the catalytic layers.

16. The nanophotocapacitive device claim 15, further comprising:
three substrates arranged in closed-spaced parallel relationship to one another, the three substrates comprising:
a center substrate having first and second faces;
a first outer substrate having an inner and outer face, the first outer substrate being arranged so that the inner face and the first face are juxtaposed; and
a second outer substrate having an inner and outer face, the second outer substrate being arranged so that the inner face of second substrate and the second face are juxtaposed,
the photovoltaic element formed between the first outer substrate and the center substrate,
the charge storage element formed between second outer substrate and the central substrate.

17. The nanophotocapacitive device claim 16, wherein
the first outer substrate is optically transparent,
the inner face of the first substrate has a transparent conducting coating formed thereon,
the first and second faces of the center substrate are electrical conductors,
the second outer substrate is an electrical conductor,
the photovoltaic element is formed between the first outer substrate and the center substrate,
the charge storage element is formed between the second outer substrate and the inner substrate,
the first and second faces of the center substrate are electrically connected.

18. The nanophotocapacitive device claim 17, wherein the center substrate is made of electrical conductor.

19. The nanophotocapacitive device claim 18, wherein the electrical conductor is Ti, W, Ni or stainless steel.

20. The nanophotocapacitive device claim 19, wherein the first and the second faces of the center substrate have a protective layer formed thereon.

21. The nanophotocapacitive device claim 20, wherein the protective layer comprises diamond or semimetallic or metallic nitrides, carbides, oxides, borides, phosphides, sulphides, silicides, antimonides, arsenides, tellurides and combinations thereof.

22. The nanophotocapacitive device claim 21, wherein the nitride is titanium nitride or zirconium nitride.

23. The nanophotocapacitive device claim 17, wherein additional diode layers formed between the photovoltaic element and either the inner face of the first substrate or first face of the center substrate.

24. A nanophotocapacitive device comprising two substrates (working electrode and counter electrode) arranged in close-spaced parallel relationship to one another;
a working electrode substrates is coated at least partially with a nanoparticulate dye sensitised layer of wide band gap semiconductor;
a counter electrode substrate is coated at least partially by a catalytic layer, and
an electrolyte is placed between the substrates, the aid device includes a charge storage layer.

25. The nanophotocapacitive device according to claim 24, wherein the charge storage layer formed between the working electrode substrate and the semiconductor layer

26. The nanophotocapacitive device according to claim 24, wherein the charge storage layer formed between the catalytic layer and the counter electrode substrate.

27. The nanophotocapacitive device according to claim 24, wherein the working electrode is divided into two groups of regions, the semiconductor layer formed on a first group of regions and the charge storage layer formed on a second group of regions.

28. The nanophotocapacitive device according to claim 24, wherein the counter electrode is divided into two groups of regions, the catalytic layer formed on a first group of regions and the charge storage layer on a second group of regions.
